(19) United States
(12) Patent Application Publication
(10) Pub. No.: US 2025/0264558 A1
(43) Pub. Date: Aug. 21, 2025

(54) MAGNETIC RESONANCE IMAGING APPARATUS

(71) Applicant: CANON MEDICAL SYSTEMS CORPORATION, Otawara-shi (JP)

(72) Inventors: Fumiyasu OTAKE, Utsunomiya Tochigi (JP); Motohiro MIURA, Yaita Tochigi (JP)

(73) Assignee: CANON MEDICAL SYSTEMS CORPORATION, Otawara-shi (JP)

(21) Appl. No.: 19/051,281

(22) Filed: Feb. 12, 2025

(30) Foreign Application Priority Data
Feb. 21, 2024 (JP) 2024-024867

(51) Int. Cl. G01R 33/385; G01R 33/36; G01R 33/54; G01R 33/58

(52) U.S. Cl. CPC G01R 33/3852; G01R 33/3607; G01R 33/543; G01R 33/583

(57) ABSTRACT

A magnetic resonance imaging apparatus according to exemplary embodiments includes a gradient magnetic field coil, a gradient magnetic field power supply, an analysis unit, a power calculation unit, and a voltage calculation unit. The gradient magnetic field coil applies a gradient magnetic field to a subject. The gradient magnetic field power supply applies a gradient magnetic field current to the gradient magnetic field coil and includes a capacitor for supplementing power therein. The analysis unit calculates, for each frequency, a current value of the gradient magnetic field current to be output to the gradient magnetic field coil in executing a pulse sequence. The power calculation unit calculates power consumption in the gradient magnetic field coil based on a resistance value for each frequency of the gradient magnetic field coil and a current value. The voltage calculation unit calculates a voltage value of the capacitor based on the power consumption.

### CROSS-REFERENCE TO RELATED APPLICATIONS

This application is based upon and claims the benefit of priority from Japanese Patent Application No. 2024-024867, filed Feb. 21, 2024, the entire contents of which are incorporated herein by reference.

### FIELD

Exemplary embodiments described in the present specification and the accompanying drawings relate to a magnetic resonance imaging apparatus.

### BACKGROUND

Magnetic resonance imaging apparatuses are imaging apparatuses that excites nuclear spins of a subject placed in a static magnetic field with high radio frequency (RF) signals with Larmor frequency and reconstructs magnetic resonance (MR) signals generated from the subject in response to the excitation to generate an image.

In a magnetic resonance imaging apparatus, there is a conventional technique for calculating power consumption of gradient magnetic field coils (active shield gradient coil [ASGC]) illustrated in FIG. 8 using an equivalent circuit model of the gradient magnetic field coils, predicting a voltage drop in an electrolytic capacitor in gradient magnetic field power supplies, and determining the feasibility of executing the pulse sequence.

The gradient magnetic field power supplies are each a power supply that supplies a certain output current waveform corresponding to pulse sequence conditions to the respective gradient magnetic field coils. The gradient magnetic field power supply includes an electrolytic capacitor for assistance in supplying power to the gradient magnetic field coil. Here, if the power supplied to the gradient magnetic field coil increases, the voltage of the electrolytic capacitor may drop. In this case, the gradient magnetic field power supply cannot output a target current waveform. In particular, a resistance value of a gradient magnetic field coil has a frequency characteristic, so that in a pulse sequence having a high frequency component such as echo planar imaging (EPI), the power consumption of the gradient magnetic field coil increases and the voltage drop in the electrolytic capacitor increases. Thus, in order to support a wide variety of pulse sequences, it is demanded that a voltage drop in the electrolytic capacitor is predicted and that the feasibility of executing the pulse sequence is determined.

In a conventional technique, it is necessary to set parameter values of coils 1, 2, and 3 in FIG. 8, such as self-inductances L1i to L3i and mutual inductances M12i and M13i, so that frequency characteristics of an equivalent circuit model are equal to actual measured values of the gradient magnetic field coil. However, adjustment of parameter values takes time and effort, and an error may occur from the actual measured values. Further, the resistance value of the gradient magnetic field coil changes also with temperature, so that in a conventional calculation method, an error further increases with a rise of the temperature of the gradient magnetic field coil, for example, immediately after a high load sequence is output.

### BRIEF DESCRIPTION OF THE DRAWINGS

FIG. 1 is a block diagram illustrating an overall configuration of a magnetic resonance imaging apparatus according to a first exemplary embodiment;

FIG. 2 is a block diagram illustrating a configuration of a gradient magnetic field power supply according to the first exemplary embodiment;

FIG. 3 is a block diagram illustrating a configuration for determining feasibility of executing a pulse sequence in the magnetic resonance imaging apparatus according to the first exemplary embodiment;

FIG. 4 illustrates an example of an output current waveform of a pulse sequence according to the first exemplary embodiment;

FIG. 5 illustrates an example of a frequency characteristic of a resistance value of a gradient magnetic field coil according to the first exemplary embodiment;

FIG. 6 illustrates an example of a result of Fourier transform performed on a current value according to the first exemplary embodiment;

FIG. 7 is a block diagram illustrating a configuration for determining feasibility of executing a pulse sequence in a magnetic resonance imaging apparatus according to a second exemplary embodiment; and

FIG. 8 illustrates an equivalent circuit model of a gradient magnetic field coil according to a conventional technique.

### DETAILED DESCRIPTION

A magnetic resonance imaging apparatus according to exemplary embodiments includes a gradient magnetic field coil, a gradient magnetic field power supply, an analysis unit, a power calculation unit, and a voltage calculation unit. The gradient magnetic field coil applies a gradient magnetic field to a subject. The gradient magnetic field power supply is a power supply that applies a gradient magnetic field current to the gradient magnetic field coil and includes therein a capacitor for supplementing power. The analysis unit determines, for each frequency, a current value of the gradient magnetic field current to be output to the gradient magnetic field coil in executing a pulse sequence. The power calculation unit calculates power consumption in the gradient magnetic field coil based on a resistance value for each frequency of the gradient magnetic field coil and a current value. The voltage calculation unit calculates a voltage value of the capacitor based on the power consumption.

Various Embodiments will be described hereinafter with reference to the accompanying drawings.

In the following exemplary embodiments, parts denoted by the same reference numerals operate in a similar manner, and duplicated descriptions are omitted as appropriate.

### First Exemplary Embodiment

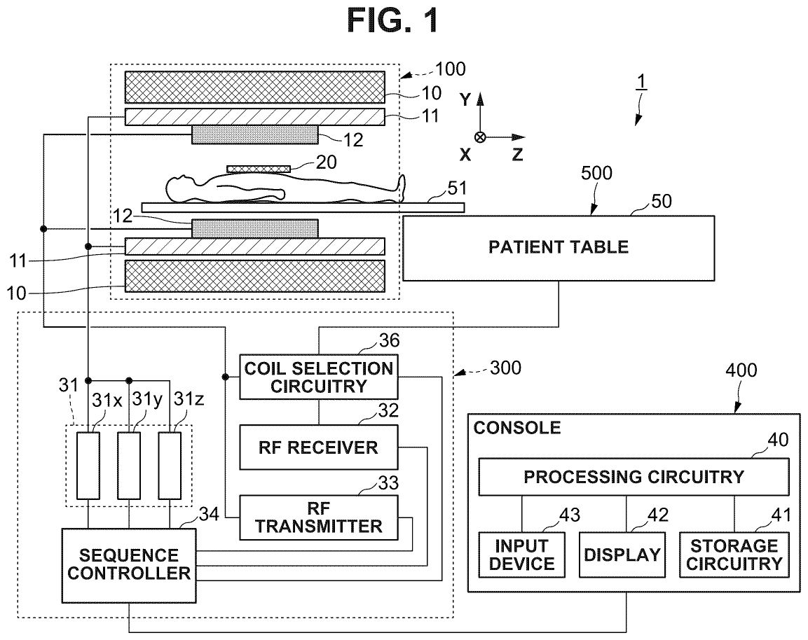

FIG. 1 is a block diagram illustrating an overall configuration of a magnetic resonance imaging apparatus 1 according to a first exemplary embodiment. The magnetic resonance imaging apparatus 1 includes a magnet rack 100, a control cabinet 300, a console 400, a patient table 500, and a radio frequency (RF) coil 20.

The magnet rack 100 includes a static magnetic field magnet 10, a gradient magnetic field coil 11, and a whole body (WB) coil 12. These components are housed in a cylindrical housing. The patient table 500 includes a patient table main body 50 and a top board 51.

The control cabinet 300 includes gradient magnetic field power supplies 31 (31x for an X-axis, 31y for a Y-axis, and 31z for a Z-axis), coil selection circuitry 36, an RF receiver 32, an RF transmitter 33, and a sequence controller 34.

The console 400 includes processing circuitry 40, storage circuitry 41, a display 42, and an input device 43. The console 400 functions as a host calculator.

The static magnetic field magnet 10 in the magnet rack 100 has a roughly cylindrical shape and generates a static magnetic field in a bore into which a subject, for example, a patient, is transported. The bore is a space inside the cylinder of the magnet rack 100. The static magnetic field magnet 10 includes a superconducting coil that is cooled to an extremely low temperature by liquid helium. The static magnetic field magnet 10 applies a current supplied from a static magnetic field power supply (not illustrated) to the superconducting coil in an excitation mode to generate the static magnetic field. Then, if the static magnetic field magnet 10 shifts to a persistent current mode, the static magnetic field power supply is disconnected from the static magnetic field magnet 10. Once the static magnetic field magnet 10 shifts to the persistent current mode, the static magnetic field magnet 10 continues to generate a large static magnetic field for a long time, for example, for one year or more.

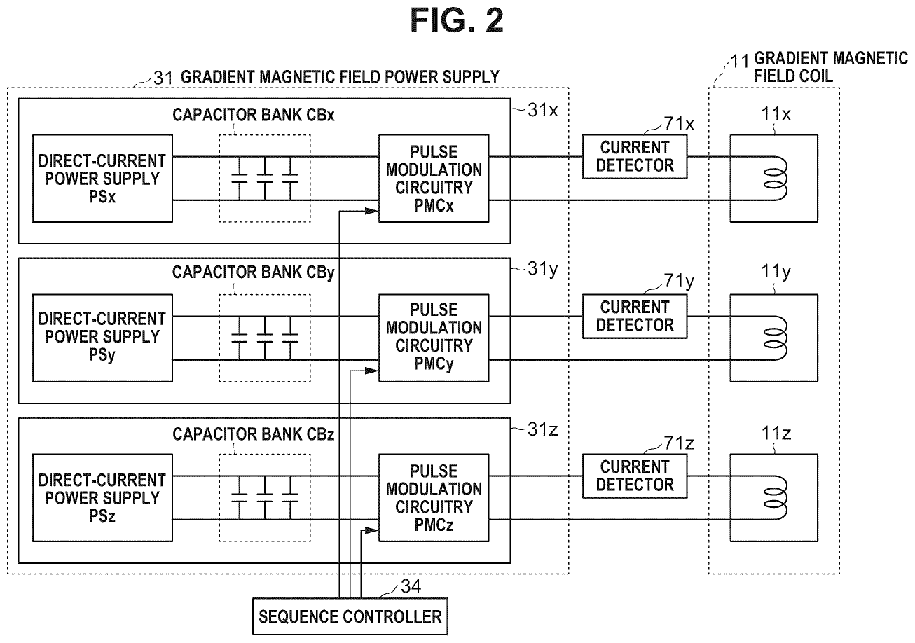

The gradient magnetic field coil 11 also has a roughly cylindrical shape and is fixed to the inside of the static magnetic field magnet 10. The gradient magnetic field coil 11 applies gradient magnetic fields to the subject in X-axis, Y-axis, and Z-axis directions by currents supplied from the gradient magnetic field power supplies 31x, 31y, and 31z, respectively. The gradient magnetic field power supply 31 is a gradient magnetic field power supply that applies the gradient magnetic field current to the gradient magnetic field coil 11 and includes therein a capacitor bank CB (see FIG. 2) for power compensation. A capacitor bank CBx is an example of a capacitor.

The patient table main body 50 of the patient table 500 can move the top board 51 in a vertical direction and a horizontal direction. The patient table main body 50 moves a subject placed on the top board 51 to a predetermined height before imaging. The top board 51 is then moved in the horizontal direction to move the subject into the bore at the time of imaging.

The WB coil 12 is also referred to as a whole body coil and is fixed to the inside of the gradient magnetic field coil 11 in a roughly cylindrical shape to surround the subject. The WB coil 12 transmits an RF pulse transmitted from the RF transmitter 33 toward the subject. Further, the WB coil 12 receives a magnetic resonance (MR) signal emitted from the subject due to excitation of hydrogen nuclei.

The magnetic resonance imaging apparatus 1 includes the RF coil 20 as illustrated in FIG. 1 in addition to the WB coil 12. The RF coil 20 is a coil placed near a body surface of the subject. The RF coil 20 includes a plurality of element coils. The plurality of element coils is arranged in an array inside the RF coil 20 and thus is sometimes referred to as a phased array coil (PAC). There are several types of RF coil 20. For example, types of the RF coil 20 include a body coil that is placed on the chest, abdomen, or legs of the subject as illustrated in FIG. 1, and a spine coil that is placed on the back of the subject.

The RF transmitter 33 generates RF pulses based on an instruction from the sequence controller 34. The generated RF pulses are transmitted to the WB coil 12 or the RF coil 20 and applied to the subject. The application of the RF pulses induces MR signals from the subject. These MR signals are received by either the RF coil 20 or the WB coil 12.

The MR signals received by the RF coil 20, more specifically, the MR signals received by each element coil in the RF coil 20 are transmitted to the coil selection circuitry 36 via cables disposed in the top board 51 and the patient table main body 50. The coil selection circuitry 36 selects a signal output from the RF coil 20 or a signal output from the WB coil in response to a control signal output from the sequence controller 34 or the console 400.

The selected signal is output to the RF receiver 32. The RF receiver 32 performs analog to digital (AD) conversion on a channel signal, namely, the MR signal, and outputs the converted signal to the sequence controller 34. The MR signal having been converted digital is also referred to as raw data. AD conversion may be performed inside the RF coil 20 or in the coil selection circuitry 36.

The sequence controller 34 scans a subject by driving the gradient magnetic field power supply 31, the RF transmitter 33, and the RF receiver 32 under the control of the console 400. In response to receiving raw data from the RF receiver 32 during the scan, the sequence controller 34 transmits the raw data to the console 400.

The sequence controller 34 includes processing circuitry (not illustrated). The processing circuitry includes hardware components, such as a processor that executes a predetermined program, a field programmable gate array (FPGA), or an application specific integrated circuit (ASIC).

The console 400 includes the storage circuitry 41, the input device 43, the display 42, and the processing circuitry 40. The storage circuitry 41 is a storage medium including a read only memory (ROM), a random access memory (RAM), and also an external storage device, such as a hard disk drive (HDD) or an optical disk device. The storage circuitry 41 stores various types of information and data, as well as various programs to be executed by a processor included in the processing circuitry 40.

The input device 43 is, for example, a mouse, a keyboard, a trackball, and a touch panel, and includes various devices for an operator to input various types of information and data. The display 42 is a display device such as a liquid crystal display panel, a plasma display panel, or an organic electroluminescence (EL) panel.

The processing circuitry 40 is, for example, circuitry including a central processing unit (CPU) or a dedicated or general-purpose processor. The processor executes various programs stored in the storage circuitry 41 to realize various functions described below. The processing circuitry 40 may be configured with hardware components, such as an FPGA and an ASIC. These hardware components can also realize various functions described below. Further, the processing circuitry 40 can also realize various functions by combining software processing through the processor and a program with hardware processing.

FIG. 2 is a block diagram illustrating a configuration of the gradient magnetic field power supply 31 according to the first exemplary embodiment. As illustrated in FIG. 2, the gradient magnetic field power supply 31 includes the gradient magnetic field power supplies 31x, 31y, and 31z. The gradient magnetic field power supply 31x includes a direct-current power supply PSx, the capacitor bank CBx, and pulse modulation circuitry PMCx. The gradient magnetic field power supply 31y includes a direct-current power supply PSy, a capacitor bank CBy, and pulse modulation circuitry PMCy. The gradient magnetic field power supply 31z includes a direct-current power supply PSz, a capacitor bank CBz, and pulse modulation circuitry PMCz.

In the gradient magnetic field power supply 31x, the direct-current power supply PSx is a power supply that supplies energy to the pulse modulation circuitry PMCx. The direct-current power supply PSx outputs a constant voltage if a downstream load is small, and switches to a constant current mode if the downstream load increases. The direct-current power supply PSx is, for example, a 400 V voltage source if the supply power is 10 KW or less. However, if the supply power exceeds 10 kw, the direct-current power supply PSx maintains a supply power of 10 KW while reducing the voltage and allowing current to flow. Additionally, the direct-current power supplies PSx, PSy, and PSz may be integrated.

The capacitor bank CBx is a capacitor that supplements the power supply that is not sufficient from the direct-current power supply PSx. The capacitor bank CBx includes, for example, a plurality of electrolytic capacitors.

The pulse modulation circuitry PMCx is a pulse amplifier that converts a waveform of a pulse sequence output from the sequence controller 34 into a large current pulse and outputs it to the gradient magnetic field coil 11x. For the pulse modulation circuitry PMCx, for example, a pulse width modulation (PWM) class D amplifier is used.

The above descriptions of the components of the gradient magnetic field power supply 31x are also applied to the components of the gradient magnetic field power supplies 31y and 31z. Gradient magnetic field currents serving as large current pulses generated by the gradient magnetic field power supplies 31x, 31y, and 31z are respectively applied to the gradient magnetic field coils 11x, 11y, and 11z. In the magnetic resonance imaging apparatus 1 according to the first exemplary embodiment, current detectors 71x, 71y, and 71z are respectively disposed between the gradient magnetic field power supplies 31x, 31y, and 31z and the gradient magnetic field coils 11x, 11y, and 11z. As described below, the current detectors 71x, 71y, and 71z measure the gradient magnetic field currents supplied from the gradient magnetic field power supplies 31x, 31y, and 31z to the gradient magnetic field coils 11x, 11y, and 11z. The current detectors 71x, 71y, and 71z may be disposed inside the gradient magnetic field power supplies 31x, 31y, and 31z, respectively.

In a case where it is necessary to apply a large current to the gradient magnetic field coils 11x to 11z for all axes in a short period of time, a required power supply amount may temporarily exceed the power that the direct-current power supplies PSx to PSz can supply. Even in such a case, the presence of the capacitor banks CBx to CBz enables a stable power supply to the gradient magnetic field coils 11x to 11z. In other words, the power from the direct-current power supplies PSx to PSz is supplemented with the power from the capacitor banks CBx to CBz, so that the supply power to the gradient magnetic field coils 11x to 11z can be maintained for as long as possible.

However, depending on a pulse sequence condition, there may be a case where the power consumption in the gradient magnetic field coils 11x to 11z increases more than expected, and even if the power is supplemented by the capacitor banks CBx to CBz, sufficient power still cannot be supplied. For example, if the frequency of the gradient magnetic field current to be used in the pulse sequence increases, the conductors of the gradient magnetic field coils 11x to 11z experience a reduction in their effective cross-sectional area due to the skin effect. As a result, resistance values of the gradient magnetic field coils 11x to 11z (i.e., pure resistance components other than reactance components of the gradient magnetic field coils 11x to 11z) become high, and a large amount of energy is consumed. In particular, an echo planar imaging (EPI) sequence has a higher frequency than a spin echo (SE) sequence, and thus consumes more energy. Accordingly, even if the capacitor banks CBx to CBz supplement the power of the direct-current power supplies PSx to PSz, sufficient power still cannot be supplied to the gradient magnetic field coils 11x to 11z. As a result, an intended gradient magnetic field cannot be applied to the subject by the gradient magnetic field coils 11x to 11z, and a normal magnetic resonance image cannot be generated. Meanwhile, there is a negative correlation between the power consumption of the gradient magnetic field coils 11x to 11z and output voltage values of the capacitors in the capacitor banks CBx to CBz (hereinbelow, simply referred to as voltage values of the capacitor banks CBx to CBz).

Thus, it is possible to estimate the power consumption of the gradient magnetic field coils 11x to 11z by monitoring the voltage values of the capacitor banks CBx to CBz. Thus, for example, a conventional magnetic resonance imaging apparatus 1 is configured such that, in a case where the voltage of the capacitor banks CBx to CBz drops to a predetermined value or less, the gradient magnetic field power supplies 31x to 31z determine that it is difficult for them to operate as power supplies to supply power to the gradient magnetic field coils 11x to 11z and shut down as an error. However, if the magnetic resonance imaging apparatus shuts down during a diagnosis of a subject, it is inconvenient because the imaging conditions, such as the pulse sequence, are to be partially modified and reset, and the imaging is to be redone.

Thus, the magnetic resonance imaging apparatus 1 according to the first exemplary embodiment has a configuration for calculating the voltage values of the capacitor banks CBx to CBz in advance and determining the feasibility of executing the pulse sequence.

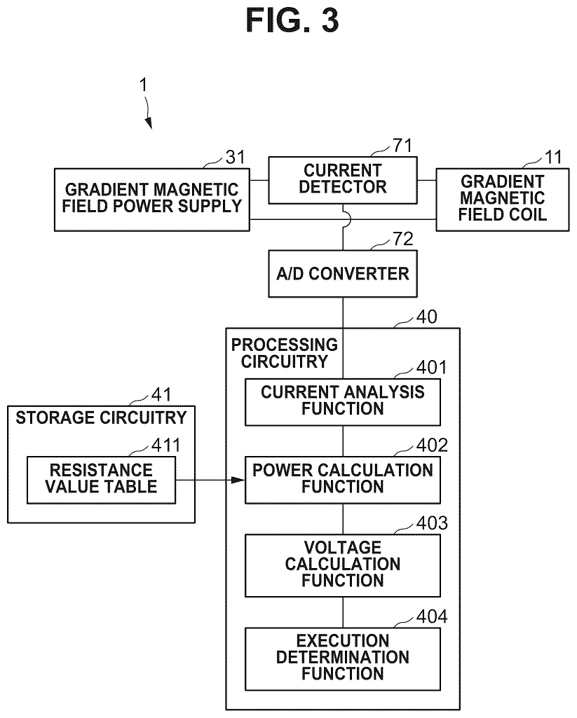

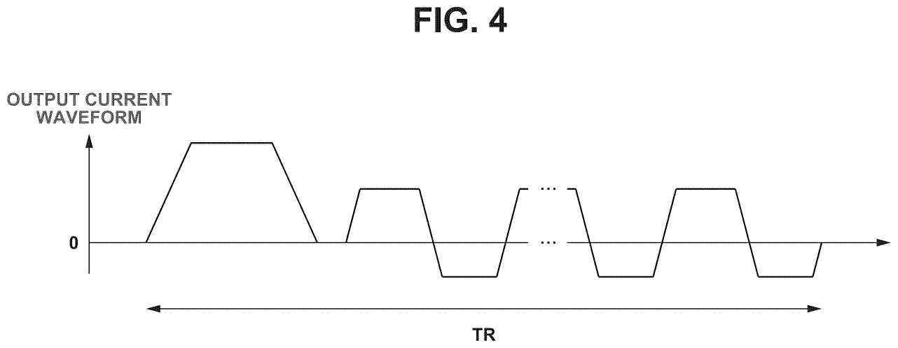

FIG. 3 is a block diagram illustrating a configuration for determining the feasibility of executing the pulse sequence in the magnetic resonance imaging apparatus 1 according to the first exemplary embodiment. As illustrated in FIG. 3, the current detector 71 is connected between the gradient magnetic field power supply 31 and the gradient magnetic field coil 11, as in FIG. 2. An analog-to-digital (A/D) converter 72 is connected between the current detector 71 and the processing circuitry 40. The current detector 71 detects a current value of the pulse sequence applied from the gradient magnetic field power supply 31 to the gradient magnetic field coil 11 and outputs the detected current value to the A/D converter 72. The A/D converter 72 acquires the current value of the pulse sequence from the current detector 71, performs analog-to-digital conversion on the acquired current value, and outputs the converted current value to the processing circuitry 40. FIG. 4 illustrates an example of an output current waveform of a pulse sequence according to the first exemplary embodiment. FIG. 4 illustrates the output current waveform for one cycle (TR, repetition pulse).

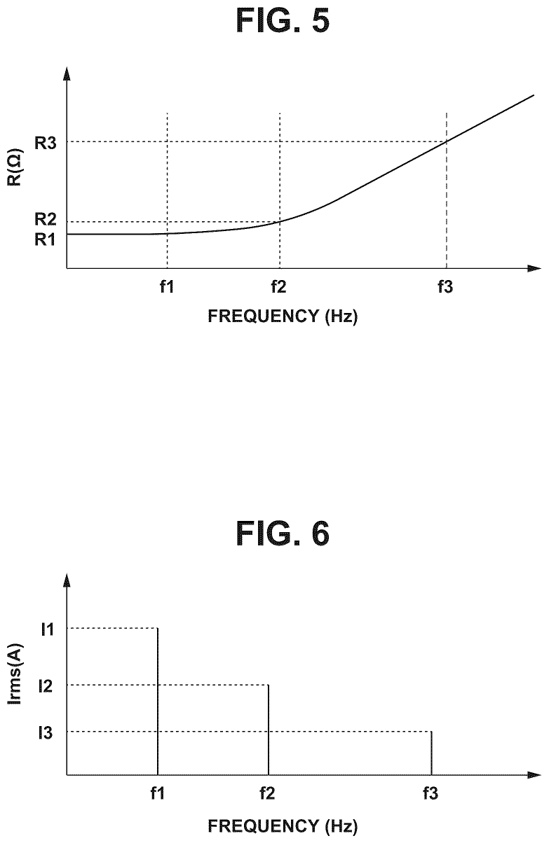

The storage circuitry 41 stores a resistance value table 411. The resistance value table 411 is a look-up table in which frequencies are in association with the resistance values of the gradient magnetic field coil 11. The resistance value for each frequency of the gradient magnetic field coil 11 is measured in advance and recorded in the resistance value table 411. FIG. 5 illustrates an example of a frequency characteristic of a resistance value of the gradient magnetic field coil 11 according to the first exemplary embodiment. For example, as illustrated in FIG. 5, frequencies f1, f2, and f3 are respectively in association with resistance values R1, R2, and R3 in the resistance value table 411.

As illustrated in FIG. 3, the processing circuitry 40 in the console 400 realizes a current analysis function 401, a power calculation function 402, a voltage calculation function 403, and an execution determination function 404. Each of these functions is realized, for example, by the processor included in the processing circuitry 40 executing a predetermined program stored in the storage circuitry 41.

The current analysis function 401 includes a function of determining, for each frequency, the current values of the gradient magnetic field currents to be output to the gradient magnetic field coils 11 in executing the pulse sequence. In detail, the current analysis function 401 acquires a digital value of the current value of the gradient magnetic field current from the A/D converter 72. The current analysis function 401 then performs a Fourier transform on the digital value of the current value and calculates the current value for each frequency. FIG. 6 illustrates an example of a result of the Fourier transform performed on a current value according to the first exemplary embodiment. It is assumed that if an output current waveform of a pulse sequence is Fourier transformed, a spectral density having a peak is acquired. As illustrated in FIG. 6, let the frequencies at which the current values peak be f1, f2, and f3, and let the effective value Irms (root mean square [RMS] value) of the current at these frequencies be I1, I2, and I3, respectively.

The power calculation function 402 includes a function of calculating power consumption in the gradient magnetic field coil 11 from the current value of the gradient magnetic field current output to the gradient magnetic field coil 11 and the resistance value of the gradient magnetic field coil 11. In detail, the power calculation function 402 acquires the resistance value for each frequency of the gradient magnetic field coil 11 from the resistance value table 411 in the storage circuitry 41. Next, the power calculation function 402 acquires the current value for each frequency from the current analysis function 401. The power calculation function 402 then calculates a power value for each frequency from the resistance value for each frequency and the current value for each frequency and totals the power values. The total value is power consumption P of the gradient magnetic field coil 11. For example, the power consumption P is calculatable using the following Equation 1,

P=R1×I1²+R2×I2²+R3×I3² Equation 1.

The voltage calculation function 403 includes a function of calculating a voltage value V of the capacitor bank CB included in the gradient magnetic field power supply 31 based on the power consumption P using the following Equation 2:

V=F(P) Equation 2,

where, F( ) is a function F that relates the power consumption P of the gradient magnetic field coil 11 to the voltage value V of the capacitor bank CB. The function F may be an approximate expression of a fitting curve calculated from a relationship between the power consumption P of the gradient magnetic field coil 11 measured in advance and the voltage value V of the capacitor bank CB or may be defined by an arithmetic expression based on the law of energy conservation as discussed in Japanese Patent Application Laid-Open No. 2017-35305. Here, energy consumption E of the gradient magnetic field coil 11 can be expressed as a following Equation 3 using Equation 1 and a time t_{TR} of one cycle of the pulse sequence,

E=(R1×I1²+R2×I2²+R3×I3²)×t_{TR} Equation 3.

Alternatively, the function F may be defined as a look-up table calculated from the relationship between the power consumption P of the gradient magnetic field coil 11 measured in advance and the voltage value V of the capacitor bank CB.

The execution determination function 404 includes a function of determining the feasibility of executing the pulse sequence based on the voltage value V of the capacitor bank CB. The execution determination function 404, for example, compares the voltage value V with a predetermined threshold value and determines that the pulse sequence is unfeasible if the voltage value V is less than the predetermined threshold value. Threshold values include a threshold value related to an interlock of the magnetic resonance imaging apparatus 1 and a threshold value related to a standard of image quality of a magnetic resonance imaging (MRI) image.

According to the first exemplary embodiment, the power consumption P of the gradient magnetic field coil 11 is calculated using an actual measured value of the gradient magnetic field current, so that time and effort in adjusting a parameter value of an equivalent circuit model can be eliminated, and an error that occurs in using the equivalent circuit model can be reduced. Further, according to the first exemplary embodiment, the power consumption P of the gradient magnetic field coil 11 is calculated using the resistance value of the gradient magnetic field coil 11, which may be different for each frequency, and frequency components of the gradient magnetic field current, so that the power consumption P of the gradient magnetic field coil 11, which reflects frequency components of the pulse sequence, can be calculated with high accuracy in accordance with a type of the pulse sequence.

### Second Exemplary Embodiment

According to the first exemplary embodiment, the resistance value table 411 in the storage circuitry 41 is used to acquire the resistance value of the gradient magnetic field coil 11. According to a second exemplary embodiment, a current to be applied to the gradient magnetic field coil 11 and a voltage of the gradient magnetic field coil 11 are acquired, and a resistance value of the gradient magnetic field coil 11 is determined from the acquired current and voltage.

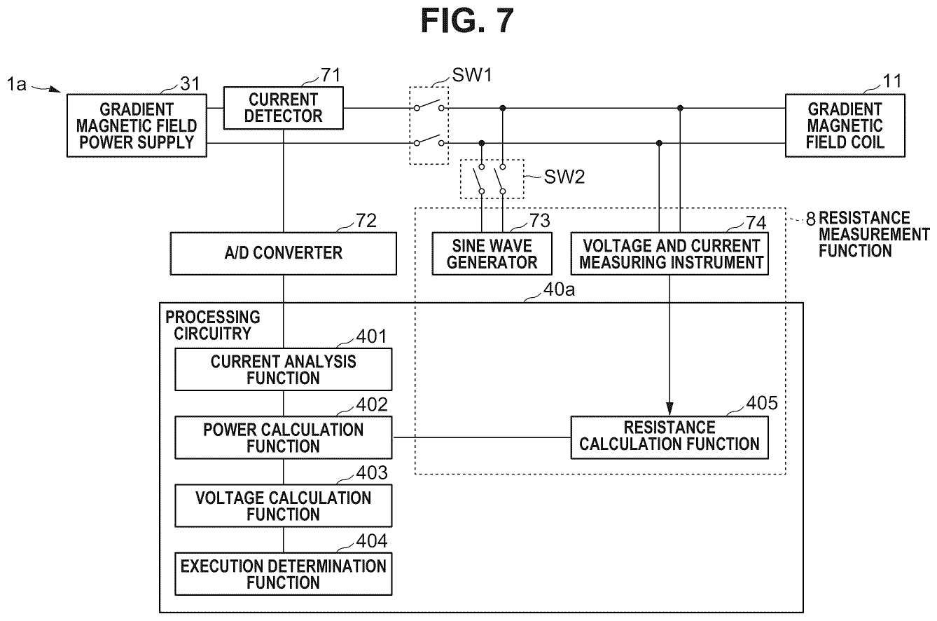

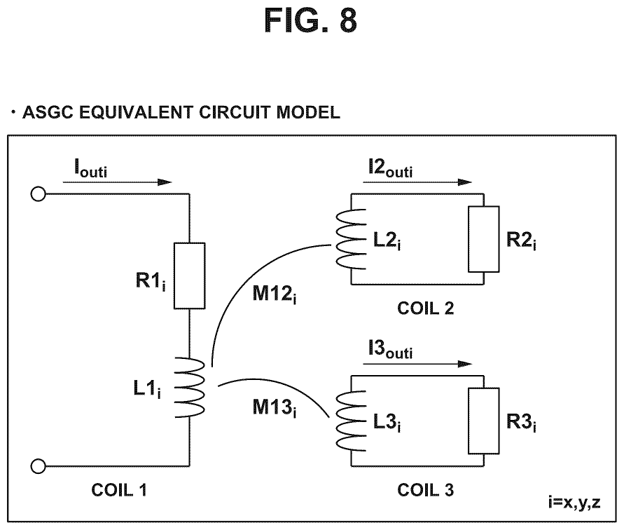

FIG. 7 is a block diagram illustrating a configuration for determining the feasibility of executing a pulse sequence in a magnetic resonance imaging apparatus 1a according to the second exemplary embodiment. Descriptions of components that are similar to those of the magnetic resonance imaging apparatus 1 are omitted below. As illustrated in FIG. 7, the magnetic resonance imaging apparatus 1a further includes a resistance measurement function 8, a first switch SW1, and a second switch SW2.

The resistance measurement function 8 includes a function of measuring a resistance value for each frequency of the gradient magnetic field coil 11. For the resistance measurement function 8, for example, an impedance meter or an impedance analyzer is used. The resistance measurement function 8 includes a sine wave generator 73, a voltage and current measuring instrument 74, and a resistance calculation function 405. The resistance calculation function 405 is realized by a processing circuitry 40a. The processing circuitry 40a has a configuration equivalent to that of the above-described processing circuitry 40 and realizes the current analysis function 401, the power calculation function 402, the voltage calculation function 403, and the execution determination function 404 in addition to the resistance calculation function 405.

The sine wave generator 73 applies a variable frequency sine wave signal to the gradient magnetic field coil 11 independently of application of the gradient magnetic field current. The voltage and current measuring instrument 74 measures a voltage and a current of the sine wave signal applied to the gradient magnetic field coil 11. The resistance calculation function 405 includes a function of calculating the resistance value for each frequency of the gradient magnetic field coil 11 from the measured voltage and current of the sine wave signal. The resistance calculation function 405 outputs the resistance value to a power calculation function 402a. At this time, the power calculation function 402a acquires the resistance value for each frequency of the gradient magnetic field coil 11 from the resistance calculation function 405.

The first switch SW1 turns on and off the connection between the gradient magnetic field power supply 31 and the gradient magnetic field coil 11. The first switch SW1 disconnects the application of the gradient magnetic field current to the gradient magnetic field coil 11 when the resistance value of the gradient magnetic field coil 11 is measured, and causes the gradient magnetic field current to be applied to the gradient magnetic field coil 11 when the resistance value is not measured.

The second switch SW2 turns on and off the connection between the sine wave generator 73 and the gradient magnetic field coil 11. The second switch SW2 causes the sine wave signal to be applied to the gradient magnetic field coil 11 when the resistance value of the gradient magnetic field coil 11 is measured, and disconnects the application of the sine wave signal to the gradient magnetic field coil 11 when the resistance value is not measured.

The resistance calculation function 405 may calculate the resistance value of the gradient magnetic field coil 11 as a pure resistance component not including an inductance component of the gradient magnetic field coil 11 from a current component that is in phase with the voltage among the voltage and current, or from a voltage component that is in phase with the current among the current and voltage. For example, if the sine wave generator 73 is a constant voltage source, the resistance value of the gradient magnetic field coil 11 is calculated from the voltage to be applied by the sine wave generator 73 and the current component in phase with the voltage. If the sine wave generator 73 is a constant current source, the resistance value of the gradient magnetic field coil 11 is calculated from the current to be applied by the sine wave generator 73 and the voltage component in phase with the current.

In addition, in a case where a second pulse sequence is to be executed after the execution of a first pulse sequence (i.e., scanning of a subject), the resistance measurement function 8 may measure the resistance value of the gradient magnetic field coil 11 after completion of the first pulse sequence and before start of the second pulse sequence.

According to the second exemplary embodiment, frequency characteristics of the resistance value of the gradient magnetic field coil 11 is measured between scans of a subject, so that it is possible to calculate the power consumption of the gradient magnetic field coil 11, which reflects a change in the resistance value of the gradient magnetic field coil 11 with temperature change. As a result, the voltage value V of the capacitor bank CB can be estimated with high accuracy, and it is possible to determine the feasibility of executing the pulse sequence with high reliability.

According to at least one of the exemplary embodiments described above, a magnetic resonance imaging apparatus can accurately determine the feasibility of executing the pulse sequence.

The current analysis function 401 is an example of an analysis unit. The power calculation functions 402 and 402a are examples of a power calculation unit. The voltage calculation function 403 is an example of a voltage calculation unit. The execution determination function 404 is an example of a determination unit. The resistance calculation function 405 is an example of a resistance calculation unit. The resistance measurement function 8 is an example of a measurement unit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
a gradient magnetic field coil configured to generate a gradient magnetic field;
a power supply configured to supply a current to the gradient magnetic field coil;
a detector configured to detect the current flowing through the gradient magnetic field coil; and
processing circuitry configured to:
determine a first value of a current having a first frequency included in the current detected by the detector based on the current detected by the detector and a second value of a current having a second frequency included in the current detected by the detector based on the current detected by the detector;
determine a third value of a resistance corresponding to the first frequency and a fourth value of the resistance corresponding to the second frequency; and
determine feasibility of executing a pulse sequence to scan an object based on the first value, the second value, the third value and the fourth value.

2. The magnetic resonance imaging apparatus according to claim 1, wherein the processing circuitry is configured to determine power consumption in the gradient magnetic field coil based on the first value, the second value, the third value and the fourth value,
wherein the processing circuitry is configured to determine feasibility of executing the pulse sequence based on the determined power consumption.

3. The magnetic resonance imaging apparatus according to claim 1, wherein the power supply includes a capacitor,
wherein the processing circuitry is configured to determine a value of a voltage of the capacitor based on the determined power consumption,
wherein the processing circuitry is configured to determine feasibility of executing the pulse sequence based on the determined value of the voltage.

4. The magnetic resonance imaging apparatus according to claim 1, wherein the first frequency and the second frequency are obtained by performing Fourier transform on a value of the current detected by the detector.

5. The magnetic resonance imaging apparatus according to claim 1, further comprising a storage in which information about a relationship between a value of the resistance and a frequency is stored,
wherein the processing circuitry is configured to determine the third value and the fourth value based on the information.

6. The magnetic resonance imaging apparatus according to claim 1, further comprising a measurement unit configured to measure a resistance value for each frequency of the gradient magnetic field coil.

7. The magnetic resonance imaging apparatus according to claim 6, wherein the measurement unit comprises:
a sine wave generator configured to apply a variable frequency sine wave signal to the gradient magnetic field coil independently of application of the gradient magnetic field current; and
a voltage and current measuring instrument configured to measure a voltage and a current of the sine wave signal applied to the gradient magnetic field coil,
wherein the processing circuitry is further configured to calculate a resistance value for each frequency of the gradient magnetic field coil from the measured voltage and current.

8. The magnetic resonance imaging apparatus according to claim 7, further comprising:
a first switch configured to disconnect application of the gradient magnetic field current to the gradient magnetic field coil when the resistance value is measured, and cause the gradient magnetic field current to be applied to the gradient magnetic field coil when the resistance value is not measured; and
a second switch configured to cause the sine wave signal to be applied to the gradient magnetic field coil when the resistance value is measured and disconnect application of the sine wave signal to the gradient magnetic field coil when the resistance value is not measured.

9. The magnetic resonance imaging apparatus according to claim 7, wherein the processing circuitry calculates the resistance value as a pure resistance component not including an inductance component of the gradient magnetic field coil from a current component in phase with the voltage among the voltage and the current, or from a voltage component in phase with the current among the current and the voltage.
